(19) United States
(12) Patent Application Publication
(10) Pub. No.: US 2025/0159825 A1
(43) Pub. Date: May 15, 2025

(54) OPS Computer Adapter

(71) Applicant: Keone Trask, Greenville, SC (US)

(72) Inventor: Keone Trask, Greenville, SC (US)

(21) Appl. No.: 18/510,025

(22) Filed: Nov. 15, 2023

(51) Int. Cl. H05K 5/02; H05K 5/00

(52) U.S. Cl. CPC H05K 5/0286; H05K 5/0018

(57) ABSTRACT

A novel pluggable computer system for use with a modern touchscreen display using an Intel open pluggable specification (OPS) slot. The invention comprises an adapter and matching OPS computer that allows connection and use of the new OPS computer with existing and prior art touchscreen displays. In this manner, the invention provides an upgrade system and method for older touchscreen devices. The invention further provides security measures that prevent use of a generic OPS computer with the touchscreen, so that manufacturers can ensure that only their product specific OPS computers are used on their touchscreen devices.

The present invention generally relates to computer systems and methods and, more particularly, to a novel pluggable computer system for use with a modern touchscreen display using an Intel open pluggable specification (OPS) slot.

### BACKGROUND OF THE INVENTION

Educational institutions have transitioned over the past two generations away from chalk board use, first to marker boards and now to touchscreen displays. These touchscreens comprise a digital display with internal touch sensors and an on-board computer for operation.

Computers are integrated into displays in many ways, with a popular means being the Intel OPS standard computer. OPS computers are essentially specialized computers with an external architecture designed to allow the computer itself to plug into a specifically-sized receiver slot on devices such as touchscreen displays. Many would suggest that the Intel OPS spec is now the industry-wide digital signage standard.

Since the introduction of digital signage in 1992 the market has seen rapid growth. Incorporating digital signage into a business typically requires an LCD or LED display and a media player as a basic setup. As the requirement for digital signage has emerged into different markets for a wide range of applications, a requirement for a standardization of hardware was required to simplify new and expanding digital signage infrastructure. It was in 2010 that the Intel Open Pluggable Specification, commonly known as Intel OPS, was born.

The Intel Open Pluggable Specification is now believed by many to be the industry standard for connecting a new standard of media player into a display via a universal internal slot. No longer requiring cables, an open pluggable specification computer is simply inserted into a single slot on the back of any OPS compatible display to create an all-in-one digital signage or touchscreen solution. With advancements in technology, the Intel OPS+ standard enables a broader range of Intel processors to be integrated, including Intel Xeon processors, and Intel FPGAs. It can also support 8K resolution displays or the ability to drive three separate 4K resolution displays. The size and shape of OPS enclosures is one key. All OPS PCs are housed in a 180 mm×119 mm×30 mm enclosure.

A second key is the type of connector used in OPS computers, which requires a single 80-pin connector on the back that carries all necessary communication and power between the OPS and display. Communication not only includes the video display and audio, but data from the accessible front I/O. With a uniform housing, this 80-pin connector on the back of the OPC PC provides a simple integration into the side of the display. OPS+ media players also feature a secondary high-speed connector to future-proof Intel's OPS solution and allow for the higher-resolution content. All I/O is housed on the front of the open pluggable specification computer for simplified access.

While this uniform standard allows many types of computers to be used in many types of displays, it also creates some problems for manufacturers. Touchscreen displays can last as long as 15 years, while their OPS computers tend to last only 3 years. This means that computer upgrades are not only possible but often preferred, rather than replacing the entire touchscreen. A problem arises when a manufacturer wishes to protect the user experience, which may be based on a specific set of functions and applications unique to its touchscreens and/or computer.

For example, a touchscreen display manufacturer may provide many proprietary applications and functions that require a specific match between hardware and software so that they design and manufacture their own OPS computers to maximize the functionality of their touchscreens. If a user were to attempt upgrade with a generic OPS computer, the result may be reduced functionality or even complete system failure due to mismatched hardware and software. Unscrupulous users may even upgrade a touchscreen display with a faster but less compatible computer and then attempt to pass it off as a newer model for sale.

What is needed is a proprietary OPS computer adapter that may be used with a standard OPS slot but containing additional external features so as to prevent generic OPS computers from being substituted in its specific OPS-compatible slot. An object of the present invention is to provide a proprietary OPS computer adapter that may be used with a standard OPS slot but containing additional external features so as to prevent generic OPS computers from being substituted in its specific OPS-compatible slot.

What is also needed is a proprietary OPS computer adapter that can accept and operate with newer OPS computer modules to provide proprietary upgrade capabilities. In this manner, manufacturers may upgrade older touchscreen computers within older touchscreen displays, while maintaining legacy functionality and often introducing new functionality. An object of the present invention is to provide a proprietary OPS computer adapter that can accept and operate with smaller and newer computer modules.

### SUMMARY OF THE INVENTION

The present invention provides a proprietary OPS computer adapter that may be used with a standard OPS computer but contains additional external features so as to prevent generic OPS computers from being substituted in its specific OPS-compatible slot.

The present invention further accomplishes the foregoing objects by providing a proprietary OPS computer adapter that can accept and operate with smaller and newer computer modules using an adapter to provide proprietary upgrade capabilities.

The present invention provides a computer for use with a touchscreen display, comprising: a receiver adapter, wherein said receiver adapter comprises a slot for accepting an OPS computer module, wherein said slot comprises: a multipin plug for connecting said receiver adapter to said OPS computer module; and at least one male portion extending outward into said slot to prevent the insertion of an OPS computer module not containing a corresponding female portion.

This embodiment of the invention may optionally be provided wherein said at least one male portion extending outward into said slot extends vertically from said slot.

This embodiment of the invention may optionally be provided wherein said at least one male portion extending outward into said slot extends horizontally from said slot.

This embodiment of the invention may optionally further comprise a second male portion extending outward into said slot to prevent the insertion of an OPS computer module not containing a corresponding second female portion.

This embodiment of the invention may optionally be provided wherein said at least one male portion extending outward into said slot comprises one vertical and one horizontal male portion extending outward into said slot.

This embodiment of the invention may optionally be provided wherein said at least one male portion extending outward into said slot comprises two vertical and two horizontal male portions extending outward into said slot.

The invention further provides a method of upgrading an OPS computer module, comprising the steps of: providing a receiver adapter, wherein said receiver adapter comprises a slot for accepting an OPS computer module, wherein said slot comprises: a multipin plug for connecting said receiver adapter to said OPS computer module; and at least one male portion extending outward into said slot to prevent the insertion of an OPS computer module not containing a corresponding female portion; and inserting an OPS computer module containing a corresponding female portion into said receiver adapter.

This embodiment of the invention may optionally be provided wherein said at least one male portion extending outward into said slot extends vertically from said slot.

This embodiment of the invention may optionally be provided wherein said at least one male portion extending outward into said slot extends horizontally from said slot.

This embodiment of the invention may optionally be provided wherein said slot further comprises a second male portion extending outward into said slot to prevent the insertion of an OPS computer module not containing a corresponding second female portion.

This embodiment of the invention may optionally be provided wherein said at least one male portion extending outward into said slot comprises one vertical and one horizontal male portion extending outward into said slot.

This embodiment of the invention may optionally be provided wherein said at least one male portion extending outward into said slot comprises two vertical and two horizontal male portions extending outward into said slot.

### DESCRIPTION OF THE DRAWINGS

The invention will be more readily understood with reference to the following specification in conjunction with the drawings herein:

FIG. 1 is a perspective view of a OPS computer adapter for use in a touchscreen display according to a preferred embodiment of the invention.

FIG. 2 is a perspective view of a OPS computer adapter for use in a touchscreen display according to a preferred embodiment of the invention.

FIG. 3 is a perspective view of an OPS computer for use in a touchscreen display according to a preferred embodiment of the invention.

FIG. 4 is a perspective view of an OPS computer for use in a touchscreen display according to a preferred embodiment of the invention.

FIG. 5 is an illustration of an OPS computer being inserted into an OPS computer according to a preferred embodiment of the invention.

FIG. 6 is an illustration of an OPS computer being inserted into an OPS computer according to a preferred embodiment of the invention.

FIG. 7 is an illustration of an OPS computer fully inserted into an OPS computer according to a preferred embodiment of the invention.

### DESCRIPTION OF THE PREFERRED EMBODIMENTS

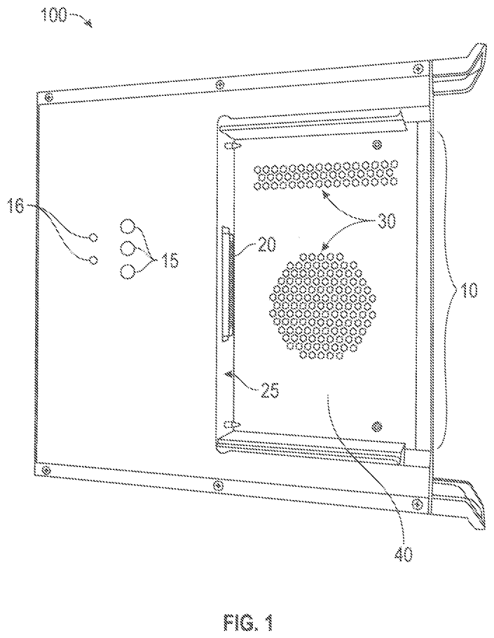

Referring now to FIG. 1, a perspective view of an OPS computer adapter 100 according a preferred embodiment of the invention is illustrated. Adapter 100 is designed to fit into legacy touchscreen displays that were made primarily from 2010 to 2020. Millions of these computers were sold and used in touchscreen displays worldwide.

Adapter 100 comprises a slot 10 designed to accept an OPS computer. Plug 20 accepts a standard OPS computer plug and is positioned along the center of backing plate 25. Vents 30 are specifically positioned to match the vent holes of a standard OPS computer. Side plate 40 provides the outer surface of slot 10 in which vents 30 are located. Power pins 15 and 16 provide power to adapter 100 when inserted into a touchscreen display.

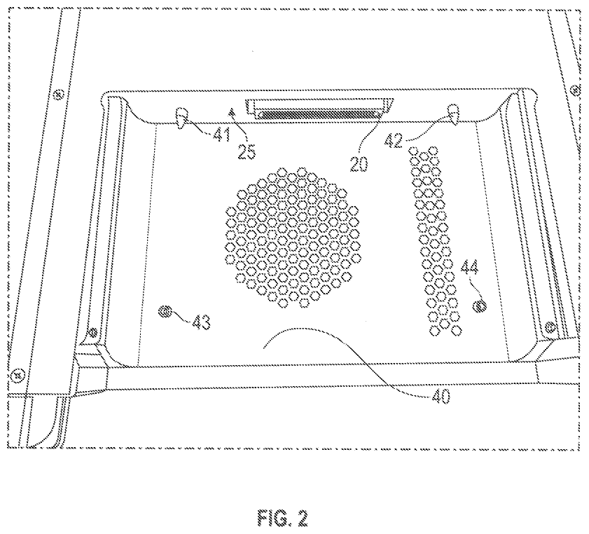

FIG. 2 provides a closer view of OPS computer adapter 100 according a preferred embodiment of the invention. In this illustration, pins 41 and 42 are shown protruding horizontally from backing plate 25 so as to project into slot 10. Pins 43 and 44 are shown protruding vertically from side plate 40 so as to project into slot 10. These pins provide the male portions of the proprietary adapter security as illustrated and explained more fully below.

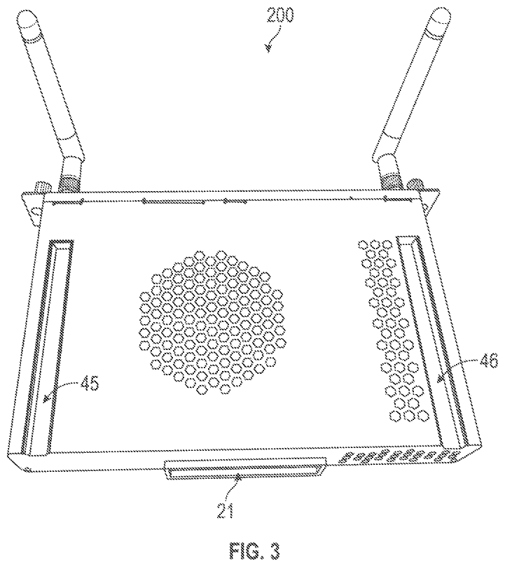

FIG. 3 illustrates a proprietary OPS computer 200, according a preferred embodiment of the invention. Computer 200 is sized to slide into slot 10 of adapter 100 illustrated in FIG. 1, where plug 21 operatively connects with plug 20.

One of the two female portions of the proprietary security mechanisms is illustrated. The vertical pins 43 and 44 from FIG. 2 are designed to operate within rails 45 and 46. More specifically, rails 45 and 46 are the female portions designed to accept pins 43 and 44.

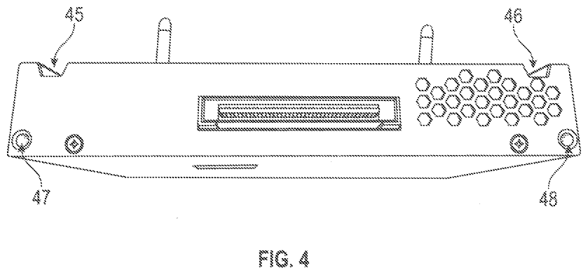

FIG. 4 illustrates all four of the female portions of the proprietary security mechanisms, according to a preferred embodiment of the invention. Vertical rails 45 and 46 are visible at this angle and further illustrate how vertical pins 43 and 44 are accepted by OPS computer 200. In addition, pin holes 47 and 48 are illustrated to show the manner in which they accept insertion of pins 41 and 42.

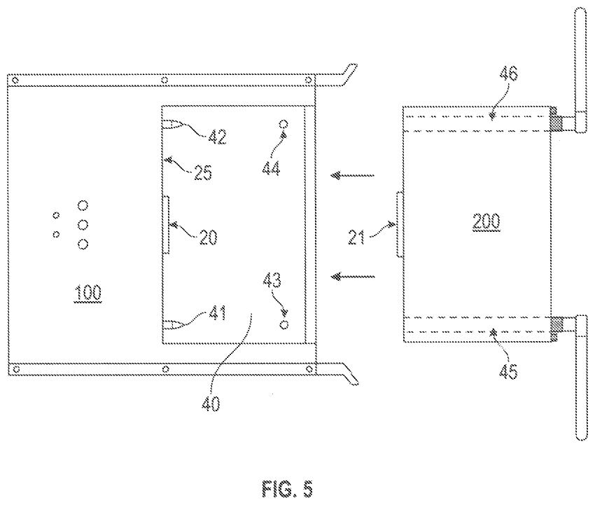

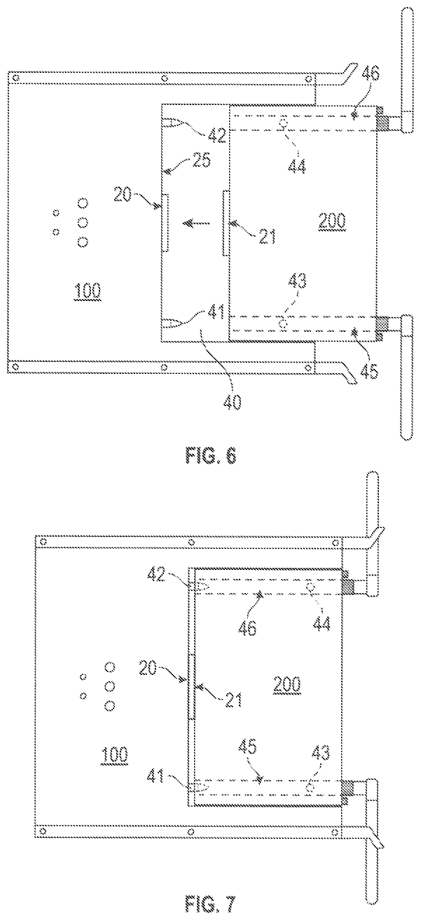

FIGS. 5 to 7 are provided to illustrate how OPS computer 200 is inserted into adapter 100, according to a preferred embodiment of the invention. The user starts as shown in FIG. 5 by aligning OPS computer 200 with slot 10 in adapter 100. As shown in FIG. 6, the user then presses OPS computer 200 into slot 10 and slides along side plate 40. When fully engaged, as shown in FIG. 7, plug 21 mates with plug 20, whereby computer 200 fully contacts backing plate 25.

In this manner, rails 45 and 46 align with and slide along pins 43 and 44. Further, pin holes 47 and 48 (not shown from this angle) provide an insertion point for horizontal pins 41 and 42. One can see from this illustration that a generic OPS computer without rails 45 and 46 or pin holes 47 and 48 would not be accepted by the adapter because each of these protruding pins 41, 42, 43, and 44 would prevent a generic OPS computer from sliding into place to connect plugs 21 with 20.

Once fully connected, as shown in FIG. 7, OPS computer 200 is available for use with a prior art touchscreen device through adapter 100. If a future user attempts to remove computer 200 and replace it with a generic OPS computer, the security devices provided by the invention will prevent such use.

The invention has been described with reference to the preferred embodiments without limit thereto. Additional embodiments and improvements may be realized which are not specifically set forth herein but which are within the scope of the invention as more specifically set forth in the claims appended hereto.

1. A computer for use with a touchscreen display, comprising:
a receiver adapter, wherein said receiver adapter comprises a slot for accepting an OPS computer module, wherein said slot comprises:
a multipin plug for connecting said receiver adapter to said OPS computer module; and
at least one male portion extending outward into said slot to prevent the insertion of an OPS computer module not containing a corresponding female portion.

2. The system of claim 1, wherein said at least one male portion extending outward into said slot extends vertically from said slot.

3. The system of claim 1, wherein said at least one male portion extending outward into said slot extends horizontally from said slot.

4. The system of claim 1, further comprising a second male portion extending outward into said slot to prevent the insertion of an OPS computer module not containing a corresponding second female portion.

5. The system of claim 1, wherein said at least one male portion extending outward into said slot comprises one vertical and one horizontal male portion extending outward into said slot.

6. The system of claim 1, wherein said at least one male portion extending outward into said slot comprises two vertical and two horizontal male portions extending outward into said slot.

7. A method of upgrading an OPS computer module, comprising:
providing a receiver adapter, wherein said receiver adapter comprises a slot for accepting an OPS computer module, wherein said slot comprises:
a multipin plug for connecting said receiver adapter to said OPS computer module; and
at least one male portion extending outward into said slot to prevent the insertion of an OPS computer module not containing a corresponding female portion; and
inserting an OPS computer module containing a corresponding female portion into said receiver adapter.

8. The method of claim 7, wherein said at least one male portion extending outward into said slot extends vertically from said slot.

9. The method of claim 7, wherein said at least one male portion extending outward into said slot extends horizontally from said slot.

10. The method of claim 7, wherein said slot further comprises a second male portion extending outward into said slot to prevent the insertion of an OPS computer module not containing a corresponding second female portion.

11. The method of claim 7, wherein said at least one male portion extending outward into said slot comprises one vertical and one horizontal male portion extending outward into said slot.

12. The method of claim 7, wherein said at least one male portion extending outward into said slot comprises two vertical and two horizontal male portions extending outward into said slot.
